(19) United States
(12) Patent Application Publication
(10) Pub. No.: US 2015/0030283 A1
(43) Pub. Date: Jan. 29, 2015

(54) Concentrating Thin Film Absorber Device and Method of Manufacture

(71) Applicant: International Business Machines Corporation, Armonk, NY (US)

(72) Inventors: Hans-Juergen Eickelmann, Nieder-Hilbersheim (DE); Harold J. Hovel, Katonah, NY (US); Ruediger Kellmann, Mainz (DE); Hartmut Kuehl, Gau-Bischofsheim (DE); Markus Schmidt, Seibersbach (DE); Steven E. Steen, Peekskill, NY (US)

(21) Appl. No.: 14/321,203

(22) Filed: Jul. 1, 2014

(30) Foreign Application Priority Data
Jul. 3, 2013 (GB) 1311815.3

(51) Int. Cl. G02B 19/00; G02B 6/136; G02B 6/12

(52) U.S. Cl. CPC G02B 19/0042; G02B 6/12002; G02B 6/136; G02B 19/0014; G02B 2006/12126; G02B 2006/12166; G02B 2006/12176
USPC 385/14; 359/350; 216/24; 264/1.1; 29/428

(57) ABSTRACT

An absorber device comprises a substrate; one or more thin film radiation absorbers arranged on the substrate; an integrated optical system, comprising at least one first optical element; a cover medium arranged above the substrate and the one or more radiation absorbers. The at least one first optical element and at least one corresponding one of the one or more radiation absorbers are aligned with respect to their optical axis, such that an incoming radiation is directed onto the one or more radiation absorbers by the optical system. A method of manufacturing an absorber device is also provided.

### BACKGROUND

The present invention relates in general to an absorber device, and in particular, to a concentrating thin film absorber device and a method for manufacturing an absorber device.

Concentrating photovoltaics is a promising technology for the conversion of sunlight into electricity. At locations in the sun belt of the earth, direct radiation (without scattering due to clouds etc.) is predominant and leads to the design of solar conversion devices that concentrate the radiation. The concentration requires an absorbing element only to exist within the illuminated area. At the same time, manufacturing process demands on discrete optical assemblies are high and variations in the manufacturing process and during operation reduce overall system efficiency.

US 2010/0012171 A1 discloses a concept of providing a simple, concentrating photovoltaic (CPV) module comprising one or more reflective sun concentrating units arranged. in one construction. Each module includes a light-weight aluminum housing tray that mounts a multitude of solar collectors having a shape approximating that of a parabola and covered by anti-reflection glass that provides a sealed environment. The focal line of such parabola is coincident with a secondary reflector which receives sunlight incident on the primary collectors and reflects such light onto a solar cell mounted in a fixed position slightly below the primary reflector and substantially concentric to the centerline of the primary collector. The primary collector is supported by a frame to add rigidity, and maintain precise location relative to the secondary reflector and the solar cell. A multitude of individual collectors is arranged side-by-side to form a solar module of desired size. Each solar concentrating system comprises primary and secondary durable, stamped aluminum collectors with highly reflective surfaces, typically silver metalized, that reflect incident sunlight many times its normal intensity onto the solar cell.

### SUMMARY

It is an objective of the invention to provide an absorber device with high efficiency at reduced costs in an integrated modular design.

Another objective is to provide a method for manufacturing an absorber device with high efficiency at reduced costs in an integrated modular design.

These objectives are achieved by the features of the independent claims. The other claims, the drawings and the specification disclose advantageous embodiments of the invention,

According to a first illustrative embodiment, an absorber device is proposed, comprising (i) a substrate; (ii) one or more thin film radiation absorbers arranged on the substrate; (iii) an integrated optical system, comprising at least one first optical element; (iv) a cover medium arranged above the substrate and the one or more radiation absorbers, wherein the at least one first optical element and at least one corresponding one of the one or more radiation absorbers are aligned with respect to their optical axes, such that an incoming radiation is directed by the optical system from the at least one first optical element onto the corresponding one of one or more radiation absorbers.

According to a second illustrative embodiment, a method of manufacturing an absorber device is proposed, comprising (i) providing a substrate; (ii) providing one or more radiation absorbers arranged on the substrate; (iii) providing an integrated optical system, comprising at least one first optical element; and (iv) providing a cover medium, which is arranged above the substrate and the one or more radiation absorbers, wherein the at least one first optical element and at least one corresponding one of the one or more radiation absorbers are aligned with respect to their optical axes.

### BRIEF DESCRIPTION OF THE SEVERAL VIEWS OF THE DRAWINGS

The present invention together with the above-mentioned and other objects and advantages may best be understood from the following detailed description of the embodiments, but not restricted to the embodiments, wherein is shown in;

FIG. 1a depicts an absorber device comprising thin film radiation absorbers and an optical system directing incoming radiation onto the radiation absorbers according to an illustrative embodiment;

FIG. 1b depicts an absorber device as shown in FIG. 1a with another arrangement of the first optical elements according to an illustrative embodiment;

FIG. 1c depicts an absorber device as shown in FIG. 1a with a further arrangement of the first optical elements according to a further embodiment;

FIG. 2 depicts an absorber device comprising thin film radiation absorbers and an optical system comprising spherical or cylindrical focusing first and second optical elements according to another embodiment;

FIG. 3 depicts an absorber device comprising thin film radiation absorbers and an optical system comprising spherical focusing first and second optical elements according to a further embodiment;

FIG. 4 depicts an absorber device comprising thin film radiation absorbers and an optical system comprising cylindrical focusing first and second optical elements according to a further embodiment;

FIG. 5 depicts an absorber device comprising thin film radiation absorbers and an optical system comprising spherical or cylindrical focusing first optical elements to another embodiment;

FIG. 6 depicts an absorber device comprising thin film radiation absorbers and an optical system comprising spherical focusing first optical elements according to a further embodiment; and

FIG. 7 depicts an absorber device comprising thin film radiation absorbers and an optical system comprising cylindrical focusing first optical elements according to a further embodiment.

### DETAILED DESCRIPTION

In the drawings, like elements arc referred to with equal reference numerals. The drawings are merely schematic representations, not intended to portray specific parameters of the invention. Moreover, the drawings are intended to depict only typical embodiments of the invention and therefore should not be considered as the scope of the invention.

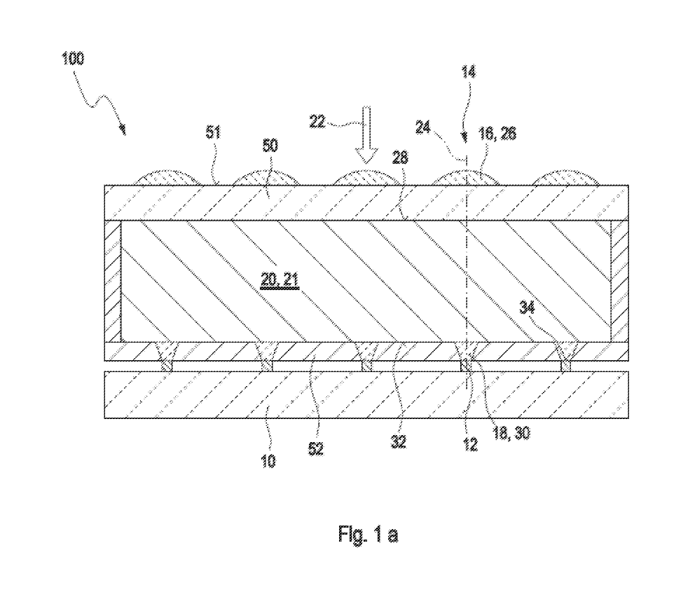

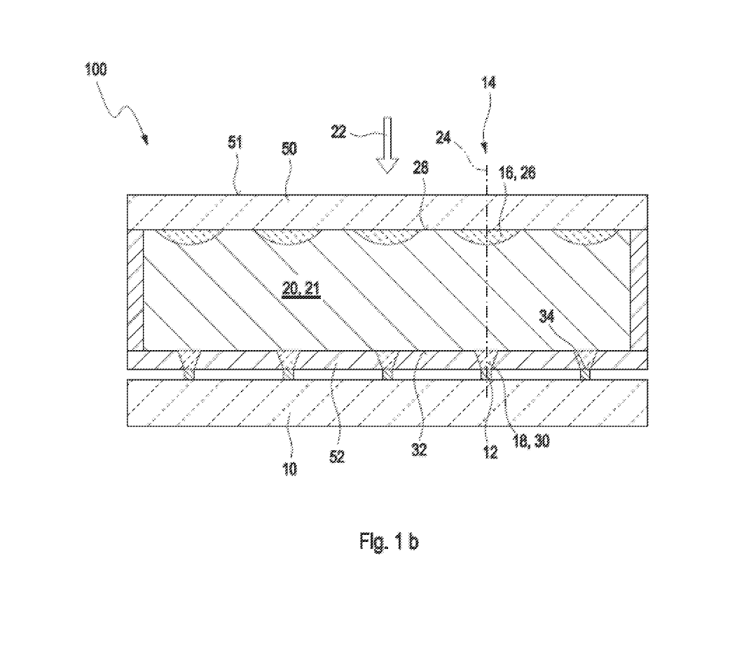

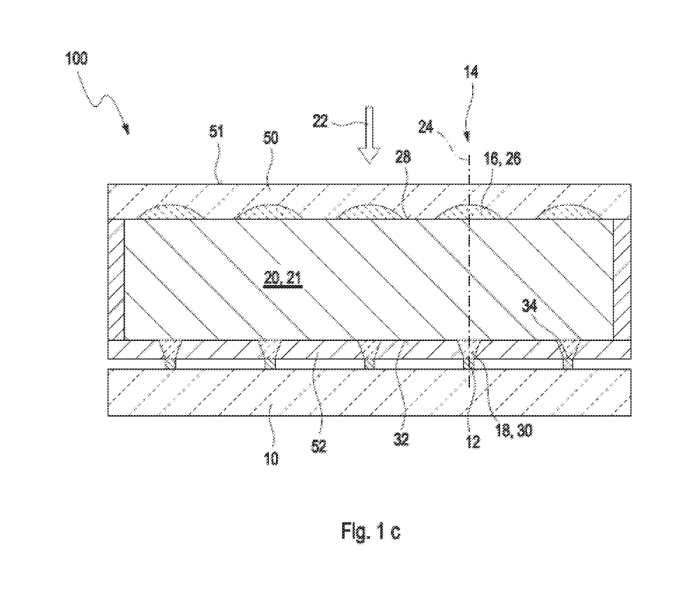

FIG. 1a exhibits an absorber device 100 comprising radiation absorbers 12 and an optical system 14 directing incoming radiation 22 onto the radiation absorbers according to an illustrative embodiment. The absorber device 100 comprises a substrate 10, a multitude of thin film radiation absorbers 12 arranged on the substrate 10 and an integrated optical system 14. The integrated optical system 14 is provided comprising first optical elements 16 and second optical elements 18, the second optical elements 18 being arranged between the first optical elements 16 and the radiation absorbers 12.

A cover medium 20 is arranged above the substrate 10 and the radiation absorbers 12. The cover medium 20 is protected by a transparent top layer 50, which may⁻ comprise a glass layer or some other transparent material. Concerning the cover medium 20, different embodiments may be realized. Like in a conventional optical system, the cover medium may comprise a cavity 21, tilled with air, inert gas or even vacuum. Another favorable embodiment may comprise a transparent solid state or even fluid layer with low refraction index, such that the incoming radiation may be focused by the optical system onto the radiation absorber device. This concerns all other embodiments shown in the following Figures.

An incoming radiation 22 is directed onto the radiation absorbers 12 by the integrated optical system 1.4. The first optical elements 16 are realized as a lens array 26, arranged on the outer surface 51 of the transparent top layer 50, especially if the top layer 50 is comprising a glass layer, whereas the second optical elements 18 are realized in the form of light guides 30, directing the incoming radiation 22 by reflecting surfaces, e.g., and integrated in an intermediate layer 52, being arranged between a bottom surface 32 of the cover medium 20 and the radiation absorbers 12. The first and second optical elements 16, 18 form corresponding pairs of such elements.

The optical system 14 comprising the first optical elements 16 and the second optical elements 18 as well as the radiation absorbers 12 are aligned to each other with respect to an optical axis 24. Particularly, each corresponding pair of first and second optical elements 16, 18 share the same optical axis 24. Incoming radiation is concentrated by the first optical elements 16 and focused onto the corresponding second optical elements 18 such that incoming radiation 22 is concentrated in the radiation absorbers 12.

Alternatively the second optical elements 1.8 may be integrated at a bottom surface 32 of the cover medium 20 or integrated at a top surface 34 of one or more radiation absorbers 12.

In a further embodiment the cover medium 20 may be attached to the radiation absorbers 12 and/or the substrate 10 directly,

As for convenience and costs manufacturing may be performed by standard thin film technologies for manufacturing of the first and/or the second optical elements 16, 18 a micro-molding/etching technique may be used.

In FIG. 1b an absorber device 100 very similar to the absorber device 100 as shown in FIG. 1a is depicted, yet with another arrangement of the first optical elements 16 according to another embodiment. In FIG. 1b the first optical elements 16 in the form of a lens array 26 are integrated on the top surface 28 of the cover medium 20, but extending their lens bodies into the cover medium 20.

In FIG. 1c an absorber device 100 is depicted, which is also very similar to the absorber device 100 as shown in FIG. 1a, yet with a further arrangement of the first optical elements 16 according to a further embodiment. Here the first optical elements 16 in the form of a lens array 26 are arranged above the top surface 28 of the cover medium 20, extending their lens bodies and thus integrated into the transparent top layer 50.

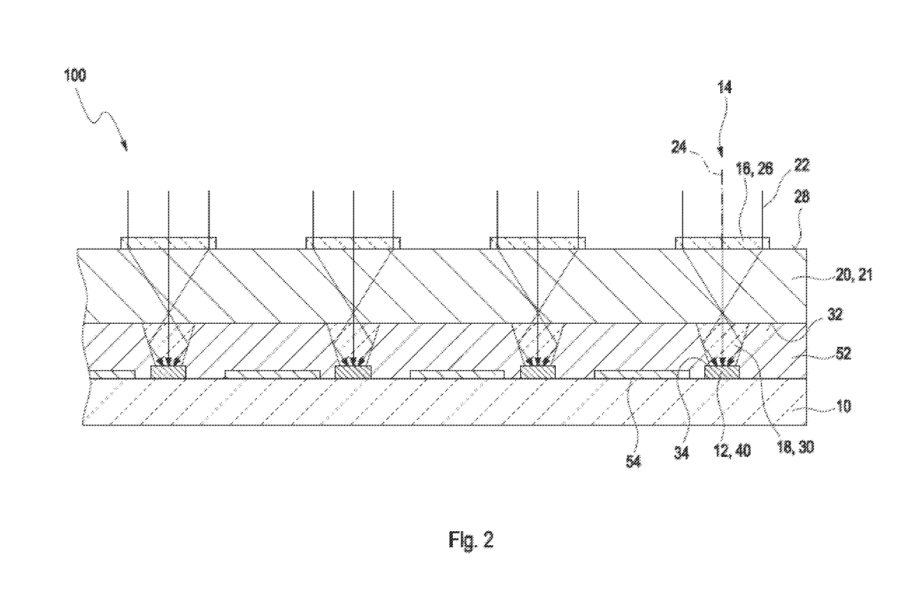

FIG. 2 exhibits an absorber device 100 comprising thin film radiation absorbers 12 and an optical system 14 comprising spherical or cylindrical focusing first and second optical elements according to another embodiment. The radiation absorbers 12 in this embodiment may comprise segmented absorbers 40 for solar light. Further in this embodiment the first optical elements 16 are attached on the top surface 28 of the cover medium 20, whereas the second optical elements 18 in the form of light guides 30 with reflecting inner surfaces are attached between the bottom surface 32 of the cover medium 20 and the top surface 34 of the radiation absorbers 12. Both, first and second optical elements may be realized as spherical or cylindrical focusing optical elements. For instance, each first optical element 16 has a corresponding second optical element 18. Between the segmented absorbers 40 interconnecting elements 54 are to be seen for electrical interconnection of the segmented absorbers 40. The space between the cover medium 20 and the substrate 10, the radiation absorbers 12, the interconnection elements 54, the second optical elements 18 may be filled with an intermediate layer in order to protect the whole system against dirt or humidity.

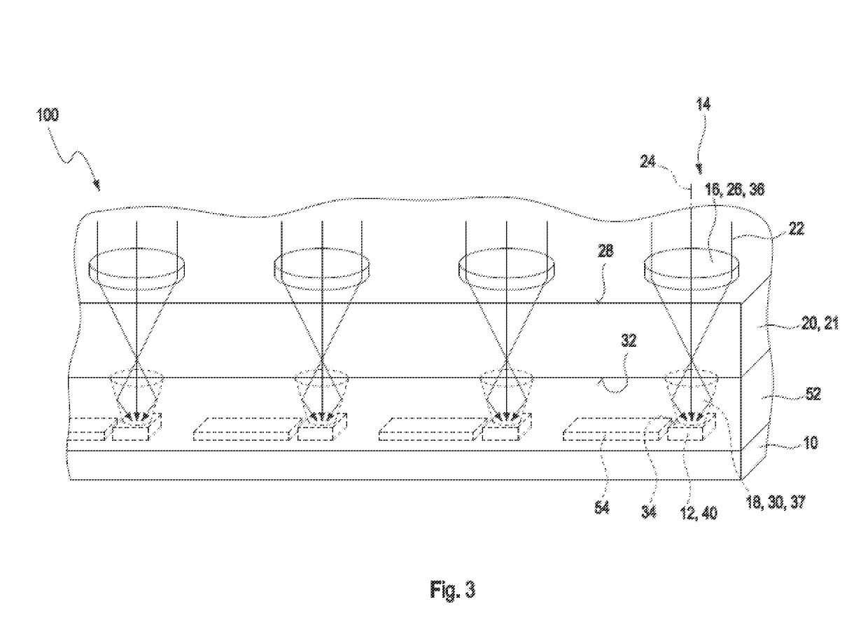

FIG. 3 shows an absorber device 100 comprising thin film radiation absorbers 12 and an optical system 14 comprising spherical focusing optical elements 36, 37 according to a further embodiment. In this embodiment the first and the second optical elements 16, 18 comprise spherical focusing first and second optical elements 36, 37. These optical elements may be realized, as lens arrays 26, where the second optical elements 37 may also be arranged in combination with additional light guides 30 in order to increase the optical efficiency of concentrating the incoming radiation 22. For instance, each first optical element 16 has a corresponding second optical element 18. Between the segmented, absorbers 12 interconnecting elements 54 are to be seen for electrical interconnection of the segmented absorbers 12.

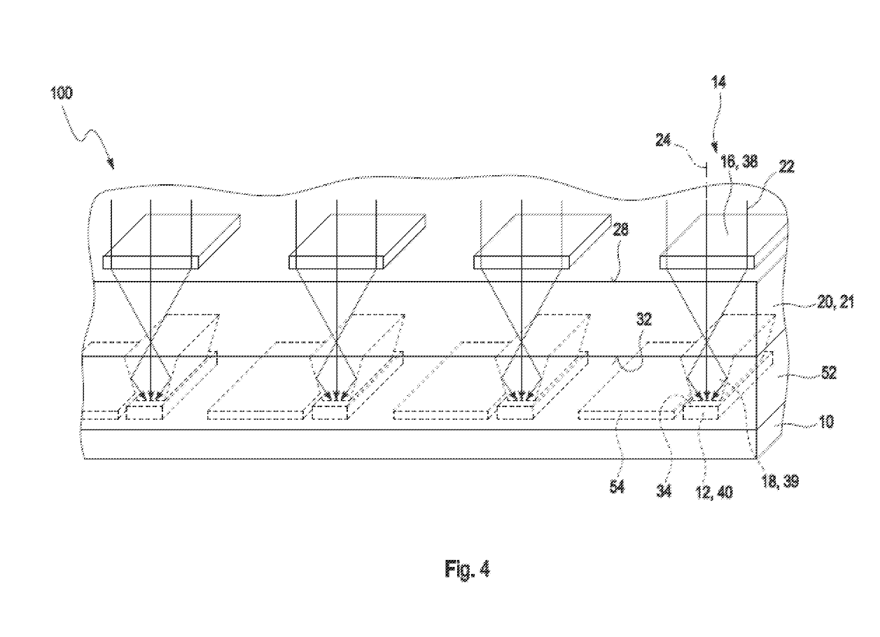

FIG. 4 exhibits an absorber device 100 comprising thin film radiation absorbers 12 and an optical system 14 comprising cylindrical focusing optical elements 38, 39 according to a further embodiment. In this embodiment the first and the second, optical elements 16, 18 comprise cylindrical focusing rectangular shaped first and second optical elements 38, 39. These cylindrical focusing optical elements 38, 39 may be realized as lens arrays like Fresnel type lenses for focusing incoming radiation 22, e.g., or in the form of light guides 34 with reflecting surfaces. The radiation absorbers 12 in this embodiment may be realized in the form of stripes, as the incoming radiation is focused onto a narrow line, in order to achieve a high efficiency for conversion of the incoming radiation 22 to electricity in the solar cells. For instance, each first optical element 16 has a corresponding second optical element 18.

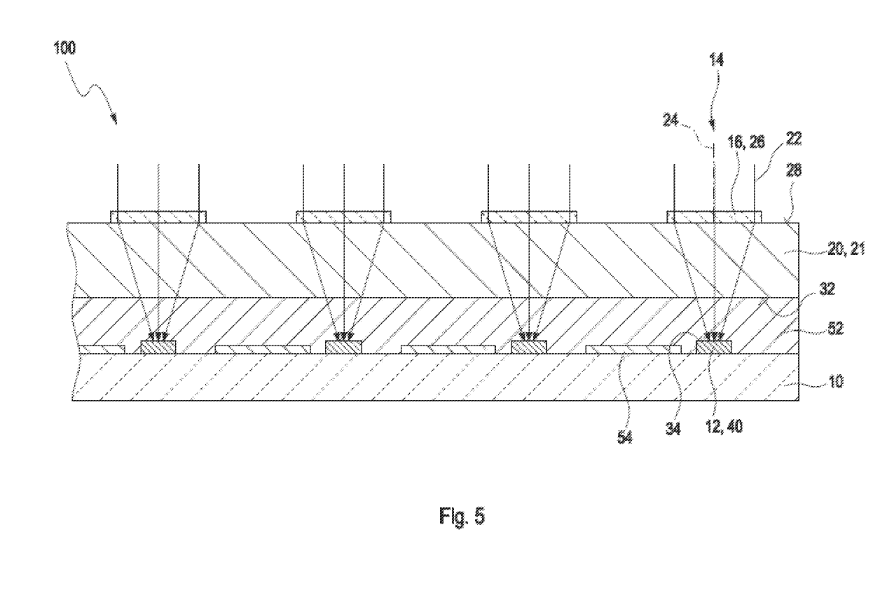

In FIG. 5 an absorber device 100 comprising thin film radiation absorbers 12 and an optical system 14 comprising spherical or cylindrical focusing first optical elements according to another embodiment is shown. This may exhibit a simpler option of an absorber device 100, where only single optical elements 16 may concentrate the incoming radiation 22 directly to a corresponding radiation absorber 12. The remaining elements of the absorber device 100 may be realized in a similar way as for the other embodiments. An advantage would be that the whole absorber device 100 may exhibit a lower thickness, because the space for a second optical element 18 is spared. Between the segmented absorbers 12 interconnecting elements 54 are to be seen for electrical interconnection of the segmented absorbers 12.

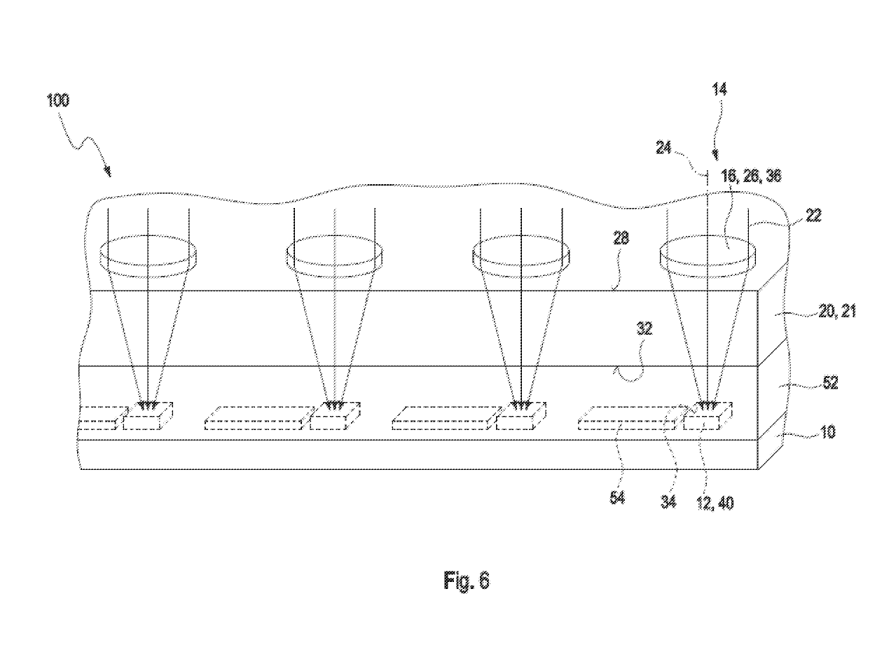

FIG. 6 shows an absorber device 100 comprising thin film radiation absorbers 12 and an optical system 14 comprising spherical focusing first optical elements according to a further embodiment. A simple lens array 26 may be used, where the lens array 26 may also be integrated in the cover medium 20 itself. Between the segmented absorbers 12 interconnecting elements 54 are to be seen for electrical interconnection of the segmented absorbers 12.

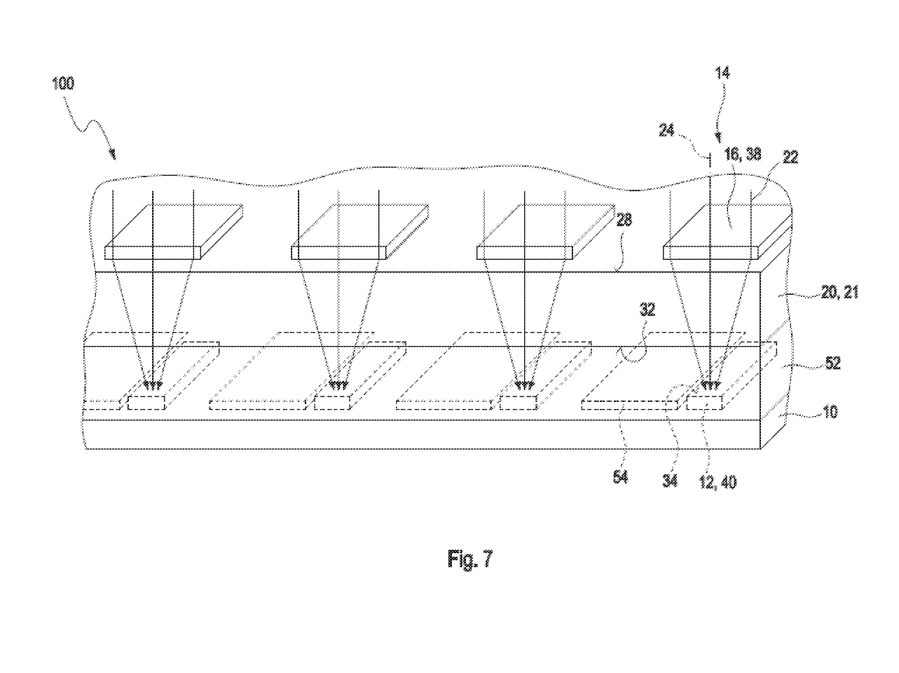

FIG. 7 exhibits an absorber device 100 comprising thin film radiation absorbers 12 and an optical system 14 comprising cylindrical focusing first optical elements according to a further embodiment. In this embodiment cylindrical focusing rectangular shaped optical elements 38, like a Fresnel type lens array, may be used for concentrating the incoming radiation 22 onto its corresponding radiation absorbers 12. Between the segmented absorbers 12 interconnecting elements 54 are to be seen for electrical interconnection of the segmented absorbers 12.

The radiation absorbers may comprise solar cells, either on semiconductor or comparable electrical elements basis, or even thermal absorbers for exploiting heat from the incoming radiation. Solar cells may be realized in thin film technology. The incoming radiation may be directed, or concentrated to the radiation absorbers by means of reflecting surfaces of optical elements or focused by means of lens arrays or combinations of the different optical techniques.

The radiation absorbers may be made of thin film elements manufactured by thin film deposition and structuring on the substrate or of separate elements on the substrate, for instance.

In order to make automated manufacturing of concentrating solar cells possible, novel manufacturing methods have been developed. Absorbers down to dimensions of millimeters are placed at distances on the order of several tens of mm (e.g. 20 mm) and this leads to reduced focal lengths of below 100 mm, determining the module height.

The efficiency of concentrating solar cell assemblies increases when the focal area is reduced as one of the major loss mechanisms is the series resistance and shading losses due to a required front surface grid.

The miniaturization can be advantageously applied for thin film solar cells. For thin film solar cells, concentration increases the conversion efficiency at modest concentrations of approximately 20 times. Up to now, thin film solar cells are mainly used as flat large area absorbers. Thin film solar cells used in conjunction with high concentration reduces materials consumption compared to standard crystalline silicon solar cells in two ways: First, thin film reduce materials usage by decreasing the required absorber thickness into the micron range. Second, high concentration reduces materials usage in lateral direction as only focal areas need to be covered, down to micron sized absorber areas. In this way, the usage of expensive and rare materials for production scales is attainable.

3D integration has led to wafer level camera designs, enabling small form factor cameras for hand-held devices. The wafer level integration of optics with CMOS image sensors and electronics allows the robust and low cost manufacturing of optics that is assembled and precision alignment taking advantage of methods from semiconductor manufacturing processes, e.g. the wafer level alignment from wafer level lithography.

In order to increase the efficiency of photovoltaic energy conversion, concentration of sunlight has proven beneficial, as the conversion efficiency depends on the photon flux and is higher at concentrations of up to 1000 times as compared to the case without concentration. For concentrating absorber devices, concentrating direct sunlight onto a small spot can lead to higher efficiencies due to higher photon flux, but also because of reduction of series resistance losses in the solar cell. If focal spots are very small, the concentrating optics can get integrated into the absorber device design arriving at a robust and low cost concentrating scheme. This will potentially decrease usage of rare materials in thin film solar cells even further, bringing manufacturing volumes without constraints due to availability of rare materials.

The main idea of the illustrative embodiments is to integrate the concentrating optical system for an absorber device into the packaging required, it provides an integration that retains the standard module format for solar cells, e.g., while increasing the solar conversion efficiency by concentration of direct incoming radiation from the sun.

One embodiment covers integrating an absorber device, like a thin film solar absorber device, with an optical system suited for the concentration of incoming radiation into the module package of a thin film absorber device, in this absorber device, a simplification of the optical system assembly is achieved, the efficiency is increased and the materials usage reduced. If the optical system is integrated into the existing module packaging, a reduction in balance of system cost is achieved as no additional costs for the optical system occur as in assemblies with discrete macroscopic optical elements. The reduction of radiation absorber size to micron dimensions is beneficial as the transparent conducting oxides used as front contacts, e.g., add high series resistance and hence losses to the standard solar cell, making concentrated thin film solar cells difficult to achieve with high concentrations. But only in the case of high concentrations the efficiency increases up to 30% are possible (The well-known single junction Shockley Queisser limit for concentrating solar cells). These losses become secondary when dimensions are small.

Concerning the optical system, an absorber device, like a thin film solar cell module package, may be modified to accommodate a concentrating optical system to focus onto a focal area of micrometer size on the top surface cover medium of the absorber device or below the bottom surface of the cover medium. As the focal spot may be so small (similar to a CD track), the focal length is also small and on the order of the module package dimensions. Concerning the cover medium, different embodiments may be realized. Like in a conventional optical system, the cover medium may comprise a cavity, filled with air, inert gas or even vacuum. Another favorable embodiment may comprise a transparent solid state or even fluid layer with a low refraction index, such that the incoming radiation may be focused by the optical system onto the radiation absorber device.

Focusing of the incoming radiation may be achieved by the first optical element, like a lens, e.g. a micro lens or a Fresnel type lens. Both cylindrical and spherical focusing methods can be used. In the case of cylindrical lenses, a focal line with micrometer width may be illuminated with concentrated incoming radiation, but with a limited concentration ratio. For highest concentrations, spherical lenses may concentrate onto a focal spot.

The integrated optical system may comprise at least one second optical element, the at least one second optical element being arranged between the at least one first optical element and the one or more radiation absorbers, wherein the at least one first optical element, the at least one second optical element and at least one corresponding one of the one or more radiation absorbers are aligned with respect to their optical axes. This second optical element may be used for increasing angle acceptance of the absorber device. The second optical element can be integrated into the package.

Advantageously the optical system and the one or more radiation absorbers may be aligned to each other with respect to an optical axis for an efficient usage of the incoming radiation and conversion by the radiation absorbers,

In a favorable embodiment the first optical element may comprise at least one lens array. Lens arrays are efficient for focusing incoming radiation with relatively low manufacturing costs.

Favorably the first optical element may be integrated at a top surface of the cover medium. An integrated packaging of the first optical element in the cover medium may be very convenient for packaging the absorber device in a way to protect the optical system against possible dirt, humidity and damage. Also it exhibits a very stable packaging status.

Advantageously the second optical element may comprise a light guide for focusing the incoming radiation which has already passed a first optical element onto a radiation absorber. This light guide may be realized as a reflecting optical element or as a lens array like the first optical element. A reflecting optical element may be efficient and cheap to manufacture,

Favorably the second optical element may be integrated at a bottom surface of the cover medium. This also serves as a stable and space efficient way of integrating the second optical element which enables to realize a flat packaging of the absorber device.

In another embodiment the second optical element may be integrated at a top surface of one or more radiation absorbers. Thus a very compact and cost effective packaging of the whole absorber device may be achieved.

Preferably, there are two main different designs of the optical system possible. A first design is based on spherical focusing optics so that the incoming radiation is concentrated in a more or less punctual focus, e.g. onto a small radiation absorber area. A second design is based on a cylindrical focusing optical element, like e.g. a Fresnel type lens, so that the incoming radiation is concentrated in a focus having linear elongation, like a stripe for instance, e.g. onto a linear radiation absorber.

Favorably the first and/or the second optical element may be of a spherical focusing type, where the optical elements may exhibit a round or oval shape. This is a very efficient way of focusing incoming radiation to points such as small radiation absorbers as may be convenient for an absorber device manufactured by standard thin film technologies.

In a farther embodiment the at least one first and/or second optical elements may be of a cylindrical focusing type, where the optical elements may exhibit a rectangular shape. Cylindrical focused radiation in the form of a narrow stripe may be achieved by one or more reflecting interfaces, for instance. Thus a linear design of an absorber device may be achieved, which might be suitable for special applications as mounting conditions and reduced losses are concerned.

Further, the one or more radiation absorbers may comprise one or more segmented absorbers for solar light. The radiation absorber, which may be a thin film absorber, can take advantage of the focused incoming radiation into a small area. A small radiation absorber stripe or spherical radiation absorber disc may be sufficient as a segmented thin film absorber for collecting the incoming radiation.

The cover medium may be attached to the radiation absorbers and/or the substrate. As standard thin film technologies and materials are used it might be convenient to embed the whole absorber device by attaching the cover medium to the radiation absorbers and/or the substrate. Thus, an optimal sealing of the radiation absorbers might be achieved which is of great advantage if the absorber device is used in humid environment.

The method of manufacture may utilize a modified package but standard module assembly manufacturing as used in standard thin film processes, e.g. The concentrating package allows to utilize, e.g., thin film solar cells for the radiation absorbers. Each radiation absorber may be manufactured in one step by a standard thin film process, which reduces manufacturing costs by a significant amount to conventional manufacturing processes of solar cells.

Thin film solar cell processing and structuring may be used for manufacturing an absorber device according to the invention. Small area absorbers may he manufactured by lithography structuring methods. For a thin film solar cell, standard deposition methods can be used. Advantageous processing schemes are electro-deposition or solvent based deposition methods as these allow to create small structures without salvaging materials due to lift off processing or the like.

Manufacturing the first and/or the second optical element may be performed by a micro-molding/etching technique. Packaging with micro-molded/etched optics may also be used as standard thin film manufacturing processes. In order to fabricate small micro-optical elements over large areas on the top surface of the cover medium, micro-molding or UV curing/etching methods may be used, e.g., to mold spherical/cylindrical lenses as an imaging optics or Fresnel type lenses as a non-imaging optics into a polymer attached/cured or spun onto or etched into an integral part of the top surface of a cover medium (e.g. glass, polymer) of an absorber device, Similarly, the structure can be transferred to the top surface cover medium material by etching methods.

A second optical element may be fabricated by micro-molding methods, attached to or micro-molded onto the bottom surface of the cover medium or in another embodiment attached to a thin film solar cell substrate side. This comprises a complete concentrating optical system in a top surface cover medium, each optical element aligned to an optical axis going through a concentrating spherical lens or Fresnel type lens and a second optical element. The optical setup is similar to a light guiding stamp.

An absorber device module level precision alignment may be performed as used in standard thin film manufacturing methods. From so called nanoimprint lithography, methods are well known in the art how to align large area glass substrates relative to each other with nanometer precision to achieve overlay of layers for semiconductor manufacturing, controlling for distortions of the patterns. After alignment, the front cover and substrate are laminated, making the optical alignment permanent.

Absorber device module packaging may be done next. After alignment, the individual absorber device layers may be assembled with required spacers and bonded or laminated into one absorber device. The form factor of this package can be similar to flat panel photovoltaic modules.

Integrating the first and/or the second optical element into the cover medium may be done. Thus a very compact and cost effective packaging of the whole absorber device may be achieved.

An advantageous manufacturing method may comprise attaching of the second optical element to the one or more radiation absorbers and/or the substrate and/or attaching the cover medium to the one or more radiation absorbers and/or the substrate. An integrated packaging may be very convenient for packaging the absorber device in a way to protect the optical system against possible dirt, humidity and damage. Also it exhibits a very stable and long living packaging status.

1. An absorber device comprising:
a substrate;
one or more thin film radiation absorbers arranged on the substrate;
an integrated optical system, comprising a first optical element;
a cover medium arranged above the substrate and the one or more radiation absorbers;
wherein the first optical element and a corresponding one of the one or more radiation absorbers are aligned with respect to their optical axes, such that an incoming radiation is directed by the integrated optical system onto the corresponding one of the one or more radiation absorbers.

2. The absorber device according to claim 1, wherein the integrated optical system comprises a second optical element, the second optical element being arranged between the first optical element and the one or more radiation absorbers and wherein the first optical element, the second optical element and the corresponding one of the one or more radiation absorbers are aligned with respect to their optical axes.

3. The absorber device according to claim 1, wherein the first optical element comprises at least one lens array.

4. The absorber device according to claim 1, wherein the first optical element is integrated at a top surface of the cover medium.

5. The absorber device according to claim 1, wherein the second optical element comprises a light guide.

6. The absorber device according to claim 1, wherein the second optical element is integrated at a bottom surface of the cover medium.

7. The absorber device according to claim 1, wherein the second optical element is integrated at a top surface of one or more radiation absorbers.

8. The absorber device according to claim 1, wherein the first or the second optical element is of a spherical focusing type.

9. The absorber device according to claim 1, wherein the first or the second optical element is of a cylindrical focusing type.

10. The absorber device according to claim 1, wherein the one or more radiation absorbers comprise one or more segmented absorbers for solar light.

11. The absorber device according to claim 1, wherein the cover medium is attached to the radiation absorbers or the substrate.

12-20. (canceled)
